(19) United States
(12) Patent Application Publication
(10) Pub. No.: US 2021/0215749 A1
(43) Pub. Date: Jul. 15, 2021

(54) CIRCUIT AND METHOD FOR RECORDING ELECTRICAL EVENTS

(71) Applicant: SEMICONDUCTOR COMPONENTS INDUSTRIES, LLC, Phoenix, AZ (US)

(72) Inventors: Jeffrey Peter GAMBINO, Gresham, OR (US); Gavin HALL, Portland, OR (US); Thomas F. LONG, Gresham, OR (US); Renaud André Jean Albert GILLON, Kruishoutem (BE); Santosh MENON, Portland, OR (US)

(73) Assignee: SEMICONDUCTOR COMPONENTS INDUSTRIES, LLC, Phoenix, AZ (US)

(21) Appl. No.: 16/739,507

(22) Filed: Jan. 10, 2020

(51) Int. Cl. G01R 31/00; H01L 27/02; G01R 31/27; G01R 31/26

(52) U.S. Cl. CPC G01R 31/002; G01R 31/2644; G01R 31/27; H01L 27/0288

(57) ABSTRACT

An event-recording circuit for recording electrical events experienced by an internal circuit in a semiconductor device is disclosed. The event-recording circuit is coupled to the internal circuit via a spark gap circuit. The spark gap circuit includes one or more encapsulated air-gap structures that are fabricated using a process flow that matches, or is adapted from, a process flow used in fabricating the semiconductor device. The event-recording circuit further includes a recording device that has an electrical property that is changed by a signal passed by the spark gap circuit, such as an ESD or EOS signal. Accordingly, a test may be performed to determine the presence, and in some cases the extent, of the change to the electrical property in a failure analysis of the semiconductor device.

### FIELD OF THE DISCLOSURE

The present disclosure relates to semiconductor circuits and more specifically to circuits for detecting and recording events of electrical overstress and/or electrical static discharge and methods of manufacturing the same.

### BACKGROUND

Semiconductor circuit/components may be damaged by electrical overstress (EOS) and/or electrical static discharge (ESD). After damage occurs, however, determining the cause as EOS or ESD can be difficult. It is in this context that implementations of the disclosure arise.

### SUMMARY

In at least one aspect, the present disclosure generally describes a circuit for recording an electrical event. The circuit includes a spark-gap circuit with at least one metal trace that defines at least one spark gap. The at least one spark gap is configured to conduct a signal during the electrical event. The circuit also include a recording device that is coupled to the spark-gap circuit and is configured to have an electrical property that is altered by the signal conducted during the electrical event. The circuit also includes a diagnostic port that is configured to provide electrical access to the recording device for an electrical test of the electrical property that was altered by the signal during the electrical event.

In one possible implementation, the circuit is directly coupled to an input/output (I/O) port of an internal circuit to monitor the electrical event at the I/O of the internal circuit. For example, the electrical event may be an electrostatic discharge (ESD) at the I/O port of the internal circuit or an electrical over stress (EOS) on the internal circuit.

In another aspect, the present disclosure generally describes a method for diagnosing damage to an internal circuit. In the method a signal is received at an input/output port of the internal circuit. The signal is also received at a spark-gap circuit, which includes at least one metal trace defining at least one spark gap, and which is coupled to the input/output port. The method includes conducting the signal through the at least one spark gap during an electrical event (e.g., ESD, EOS). The method further includes receiving the signal conducted by the at least one spark gap at a recording device coupled to the spark-gap circuit, where the recording device is configured to have an electrical property altered by the conducted signal. The method further includes coupling test equipment to a diagnostic port of the recording device and performing an electrical test on the recording device to determine the electrical property altered by the conducted signal. Based on the results of the electrical test, the damage to the internal circuit is diagnosed.

In one possible implementation of the method the at least one spark gap is a plurality of spark gaps that are each configured to couple a signal of a different amplitude. In this implementation, the method may further include visually inspecting the plurality of spark gaps to determine which spark gap (or spark gaps) of the plurality coupled the signal during the electrical event. The one or more determined spark gaps can then be correlated with a signal amplitude in order to determine an amplitude of the signal during the electrical event (or events).

In another possible implementation of the method, the recording device is a transistor; the electrical property that is altered by the conducted signal is a threshold voltage of the transistor; and the electrical test performed on the transistor is a measurement of the threshold voltage of the transistor.

In another possible implementation of the method, the recording device is a field-effect device; the electrical property that is altered by the conducted signal is a capacitance or an inductance of the field-effect device; and the electrical test performed on the field-effect device is a measurement of the capacitance or the inductance of the field-effect device.

In another possible implementation of the method, the recording device is a resistor; the electrical property that is altered by the conducted signal is a resistance of the resistor; and the electrical test performed on the resistor is a measurement of the resistance of the resistor.

In another possible implementation of the method, a control device that is substantially equivalent to the recording device is provided. The control device does not receive a signal from the spark-gap circuit during the electrical event. According, test equipment may be coupled to a control-diagnostic port of the control device so that an electrical test may be performed on the control device to determine an electrical property of the control device. The electrical property of the control device is then compared to the electrical property of the recording device altered by the conducted signal, and the damage to the internal circuit may be diagnosed based on the comparison.

In another aspect, the present disclosure generally describes a semiconductor device that includes an internal circuit having an input/output port. The semiconductor device further includes an event-recording circuit that is configured to record an electrical event at the input/output port of the internal circuit to facilitate diagnosis of damage to the internal circuit. The event-recording circuit includes a spark-gap circuit, a recording device, and a diagnostic port. The spark-gap circuit includes at least one metal trace that defines at least one spark gap. The at least one spark gap is an air-gap structure encapsulated by an inorganic dielectric that is configured to conduct a signal during the electrical event. The recording device is coupled to the at least one spark gap and is configured to have a property that is altered by the signal. The diagnostic port is configured to provide access to the recording device for a test of the property altered by the signal.

The foregoing illustrative summary, as well as other exemplary objectives and/or advantages of the disclosure, and the manner in which the same are accomplished, are further explained within the following detailed description and its accompanying drawings.

### BRIEF DESCRIPTION OF THE DRAWINGS

FIG. 1 is a block diagram illustrating a semiconductor device according to an implementation of the present disclosure.

FIG. 2 is a block diagram illustrating an event-recording circuit according to a possible implementation of the present disclosure.

FIGS. 3A, 3B, and 3C are block diagrams illustrating possible spark gap arrangements according to possible implementations of the spark-gap circuit of FIG. 2.

FIGS. 4A, 4B, and 4C are top views illustrating circuit traces for various implementations of spark gaps for the spark-gap circuit of FIG. 2.

FIGS. 5A, 5B, and 5C schematically illustrate various implementations of recording devices for the spark-gap circuit of FIG. 2.

FIG. 6 is a cross-sectional side-view of an encapsulated-air-gap structure than can be implemented as a spark gap.

FIGS. 7A, 7B, and 7C are cross-sectional side-views of a possible encapsulated-air-gap structure at various stages of fabrication using semiconductor processing.

FIGS. 8A, 8B, 8C, and 8D are cross-sectional side-views of a possible encapsulated-air-gap structure at various stages of fabrication using semiconductor processing.

FIGS. 9A, 9B, 9C, 9D, 9E, and 9F are cross-sectional side-views of a possible encapsulated-air-gap structure at various stages of fabrication using semiconductor processing.

FIGS. 10A, 10B, and 10C are cross-sectional side-views of a possible encapsulated-air-gap structure at various stages of fabrication using semiconductor processing.

The components in the drawings are not necessarily to scale relative to each other. Like reference numerals designate corresponding parts throughout the several views.

### DETAILED DESCRIPTION

The present disclosure describes a circuit for recording an electrical event (i.e., an event-recording circuit). When the event-recording circuit is coupled to an input/output (I/O) port of an internal circuit (e.g., an integrated circuit) then the event-recording circuit may be used to record one or more electrical events at the input/output port. Further, in some implementations the recording provided by the event-recording circuit (i.e., the recording) may be able to provide information regarding the severity of the ESD events or the EOS events. Accordingly, the recording may provide information including (but not limited to) whether or not an electrical event has occurred, how many times the electrical event has occurred, and the severity of the electrical event (or events). This information can be used to interpret (i.e., conclude) electrical conditions experienced by the internal circuit. For example, the recording can provide a historic record of the electrical conditions experienced by the internal circuit. This historic record may provide information that can be used for a variety of purposes related to the service of the internal circuit. For example, the recording may help diagnose a cause of a malfunction or damage to the internal circuit. This diagnosis may be used to service the internal circuit or may be used to gain information helpful for future designs and/or specifications of the internal circuit.

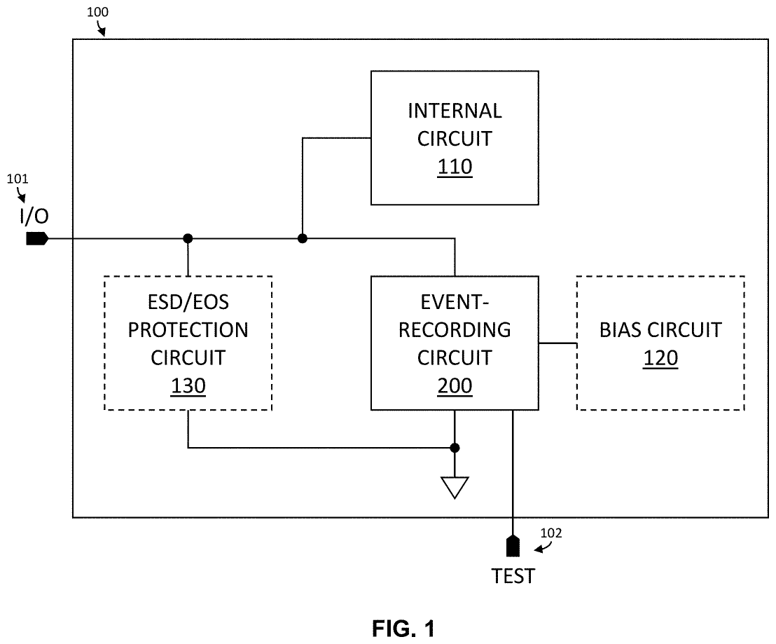

FIG. 1 is a block diagram illustrating a device (e.g., a semiconductor device) configured for recording an electrical event according to an implementation of the present disclosure. The device 100 includes an I/O port 101 that is configured to transmit/receive electrical signals from other devices, circuits, and/or systems (not shown). Received electrical signals at the I/O port 101 are intended for use by an internal circuit 110 and are generally specified to be within an operating range corresponding to the internal circuit 110. For example, signals at the I/O port 101 that are above a maximum level or below a minimum level defined by the operating range may cause damage to the internal circuit 110. This damage may correspond to improper operation of the internal circuit 110 or no operation (i.e., failure) of the internal circuit 110. In some cases, received signals outside the operating range may cause no damage to the internal circuit but may still be undesirable. For example, the electrical events may have a cumulative negative effect on the internal circuit 110 that is not immediately detectable.

The electrical events at the I/O port 101 generally include signals that cause electrical stress on the internal circuit. The electrical stress may be an electrical over stress (EOS) in which a signal (e.g., a voltage) is outside an operating range of the internal circuit. The EOS may occur for a period, which may be short, long, periodic, transient, or continuous, causing damage resulting from excess power dissipated in the internal circuit in the form of heat. One type of EOS that is severe in amplitude and transient in nature is electro-static discharge (ESD) that can be caused from a static discharge at the I/O port 101. EOS is a common failure in semiconductor circuits (i.e., integrated circuits). When a device 100 (e.g., semiconductor device) is returned to a vendor for failure, often EOS is the cause. Diagnosing EOS as the cause of the failure, however, can be difficult. Accordingly, it may be desirable to detect and record one or more electrical events (e.g., EOS events, ESD events) at the I/O port 101 of the internal circuit 110.

The device 100 further includes an event-recording circuit 200 that is configured to detect and record one or more electrical events at the I/O port 101 of the internal circuit 110. The event recording circuit is coupled to the I/O port 101 and is configured to monitor the signals to and from the internal circuit 110. When a signal at the I/O port reaches a condition corresponding to an electrical event, the event-recorded circuit 200 is configured to receive the signal and is altered by the signal. The event recording circuit 200 may include one or more diagnostic ports 102 (i.e., test ports, monitoring ports) in which the event-recording circuit can be accessed (e.g., by electrical test equipment) to obtain the recorded information.

In some implementations, the device 100 may include a bias circuit 120 that is configured to provide an electrical signal (e.g., voltage, current) to condition the operation of the event recording circuit 200. For example, the condition corresponding to an electrical event may correspond to a bias signal (e.g., a voltage) applied to the event-recording circuit 200 by the bias circuit 120. The device 100 may further include an ESD/EOS protection circuit 130. The ESD/EOS protection circuit 130 may be coupled to the I/O port 101 of the device (e.g., coupled in parallel with the event-recording circuit 200) and may be configured to couple (i.e., short circuit) an ESD/EOS signal to ground to prevent it from reaching the internal circuit 110. The threshold at which the ESD/EOS protection circuit 130 couples the ESD/EOS signal to ground may be adjusted to be greater than the threshold at which the ESD/EOS signal is coupled to event recording circuit 200 so that an increasing ESD/EOS signal is recorded by the event-recording circuit 200 before being shorted to ground by the ESD/EOS protection circuit 130. Alternatively, the threshold at which the ESD/EOS signal is coupled to event recording circuit 200 may be higher than the threshold at which the ESD/EOS protection circuit 130 couples the ESD/EOS signal to ground so that the recording circuit does not record until the ESD/EOS protection circuit 130 ceases to protect the internal circuit from an electrical event.

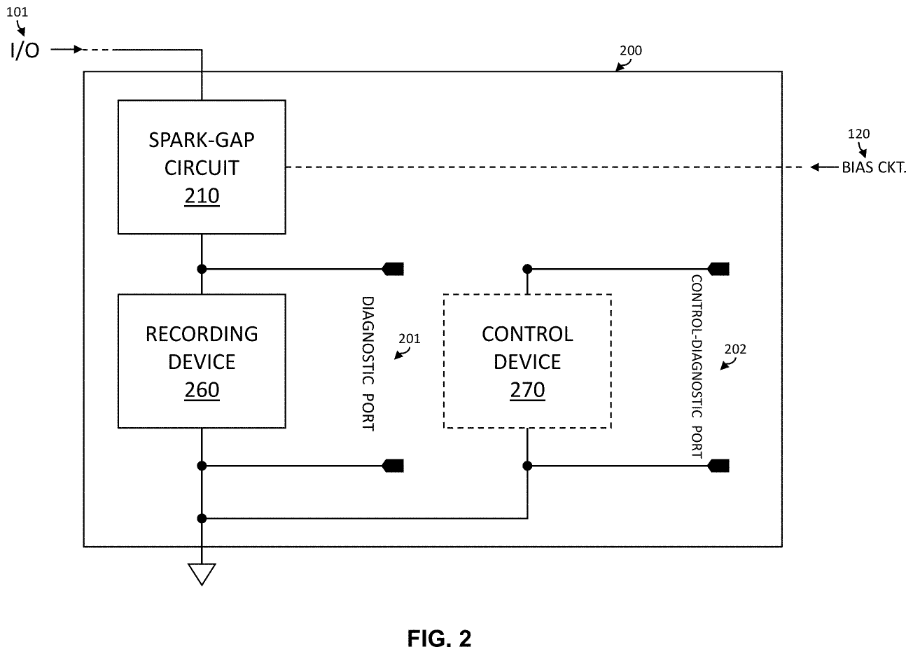

FIG. 2 is a block diagram illustrating a possible implementation of the event-recording circuit 200. As shown, the event-recording circuit 200 includes a spark-gap circuit 210. The spark-gap circuit 210 can be coupled between the I/O port 101 and a recording device 260 and can be configured to pass a signal corresponding to an electrical event to the recording device 260, and to otherwise block signals from reaching the recording device. In other words, the spark-gap circuit may provide a threshold for signals that are recorded by the recording device. For example, signals having an amplitude that is greater than a threshold (e.g., trigger voltage) of the spark-gap circuit 210 will be received by the recording device 260 but signals having amplitudes less than the conduction threshold (e.g., trigger voltage) of the spark-gap circuit 210 will not be received by the recording device 260. In some implementations the spark-gap circuit 210 is configured to also receive a signal (e.g., a bias voltage) from a bias circuit 120, which can control the threshold (e.g., trigger voltage) of the spark-gap circuit.

As shown in FIG. 2, the recording device 260 may be coupled to a diagnostic port 201. The diagnostic port may be used to access the recording device. For example, the diagnostic port may be an electrical port having a positive terminal and a negative terminal, and an electrical test may be performed on the recording device by coupling electrical equipment (e.g., test equipment) to the positive/negative terminals of the diagnostic port. Typically, normal operation of the device 100 requires no electrical equipment to be coupled to the diagnostic port. Rather, the test equipment may be coupled as necessary to the diagnostic port. For example, after the device 100 begins not operating or not operating properly, test equipment may be coupled to the diagnostic port 201 to run one or more electrical tests to determine if one or more electrical events have taken place (i.e., at an earlier time) at the I/O port 101. In some implementations, the electrical test (or tests) can validate the experience of an earlier electrical event. In some implementations, the electrical test may further provide information regarding the number of electrical events and/or the severity (e.g., the amplitude) of the electrical event (or events).

As shown in FIG. 2, the event recording circuit 200 may optionally include a control device 270. In one possible implementation, the control device 270 and recording device 260 are configured to operate substantially the same (e.g., identically), while in another implementation, the control device 270 and the recording device 260 are configured to operate with a predictable difference. The similarity or the difference in operation may be determined in a baseline calibration. The control device 270 may be coupled to a control-diagnostic port 202. The control-diagnostic port 202 may be used to access the control device 270. For example, the control-diagnostic port may be an electrical port having a positive terminal and a negative terminal, and an electrical test may be performed on the control device by coupling electrical equipment to the positive/negative terminals of the control-diagnostic port. The control device 270 may not be coupled to the spark-gap circuit 210 or the I/O port 101, and therefore, may not experience an electrical event as the recording device 260 does (i.e., the recording device receives no signal from the spark-gap circuit during the electrical event). Accordingly, electrical tests may be performed on the recording device 260 and on the control device 270 and information regarding the electrical event may be obtained by comparing the test results from the recording device 260 with test results from the control device.

The diagnostic port may be other than electrical port described above. For example, the diagnostic port 201 can a port for a visual inspection. Further, the diagnostic port for visual inspection may include or may be exclusively directed to the spark-gap circuit 210. In these implementations, the diagnosis port may facilitate a visual inspection of the spark-gap circuit 210 and/or the recording device 260 for damage and/or discoloration. This visual inspection may include optical viewing devices (e.g., magnifying optics) and/or optical recording devices (e.g., camera). The damage and/or discoloration information obtained through the visual inspection that the spark-gap circuit 210 has experienced one or more electrical events.

The spark-gap circuit 210 includes at least one spark gap. A spark gap includes a first electrode (i.e., conductor, trace) and a second electrode (i.e., conductor, trace) separated by a gap-width. An electric spark may pass between the first electrode and the second electrode when a voltage exists between the first electrode and the second electrode that is higher than a breakdown voltage (i.e., trigger voltage) of the gap-width. The breakdown voltage of the spark-gap may correspond to the gap-width so that a larger gap-width has a larger breakdown voltage than a smaller gap-width.

The spark gap may be an air-gap structure in which no material fills the gap-width between the first electrode and the second electrode. Further, the air-gap structure may be encapsulated. An encapsulated-air-gap structure can allow for a vacuum to be created in the gap-width between the first electrode and the second electrode. The vacuum created may be characterized by a pressure level that is less than an ambient pressure level (e.g., in a range from 1 milli-Torr to 100 milli-Torr). The breakdown voltage of the spark-gap may further correspond to the pressure level of the vacuum in the gap-width so that a lower-pressure vacuum has a higher breakdown voltage than a higher-pressure vacuum. The spark-gap circuit 210 may include multiple spark gaps implemented as encapsulated air-gap structures to provide multiple breakdown voltages or to create an overall breakdown voltage for the spark-gap circuit that is higher than provided by a single encapsulated air-gap structure.

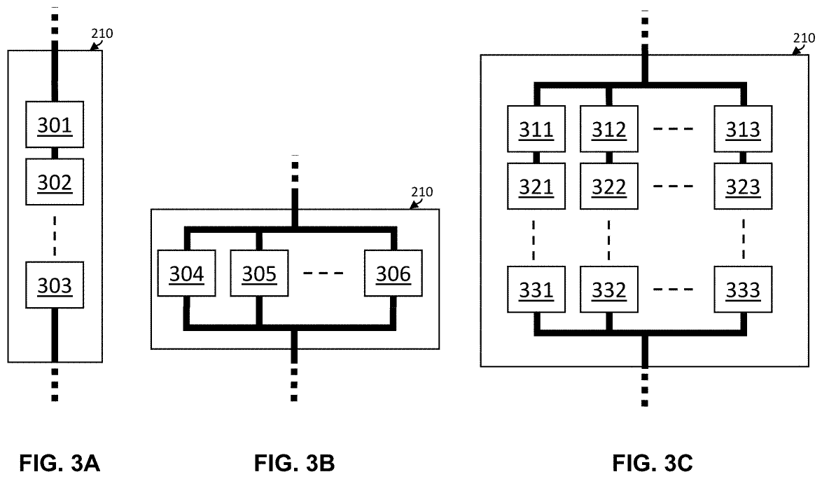

The spark-gap circuit 210 may include multiple spark gaps arranged in various configurations. FIGS. 3A-C are block diagrams illustrating possible spark gap arrangements according to possible implementations of the spark-gap circuit of FIG. 2. As shown in FIG. 3A, the spark-gap circuit 210 may include spark gaps 301, 302, 303 in a series arrangement. As shown in FIG. 3B, the spark-gap circuit 210 may include spark gaps 304, 305, 306 in a parallel arrangement. As shown in FIG. 3C, the spark-gap circuit 210 may include spark gaps 311, 321, 331, 312, 322, 332, 313, 323, 333 that are in both series and parallel arrangements. The present disclosure is not limited to any number or arrangement of spark gaps in the spark-gap circuit 210. Additionally, the present disclosure recognizes that the plurality of spark gaps in an arrangement may be the same (i.e., all the spark gaps are identically configured) or different.

A spark-gap circuit 210 may be fabricated as a metallic (e.g., Al, Cu, W, TiN, doped poly-Si) circuit trace or circuit traces. The material of the metal trace may be chosen based on a melting point, which can correspond to a current carrying capability of the trace. The circuit trace or traces a disposed on a substrate using photolithographic and chemical processing steps associated with semiconductor processing.

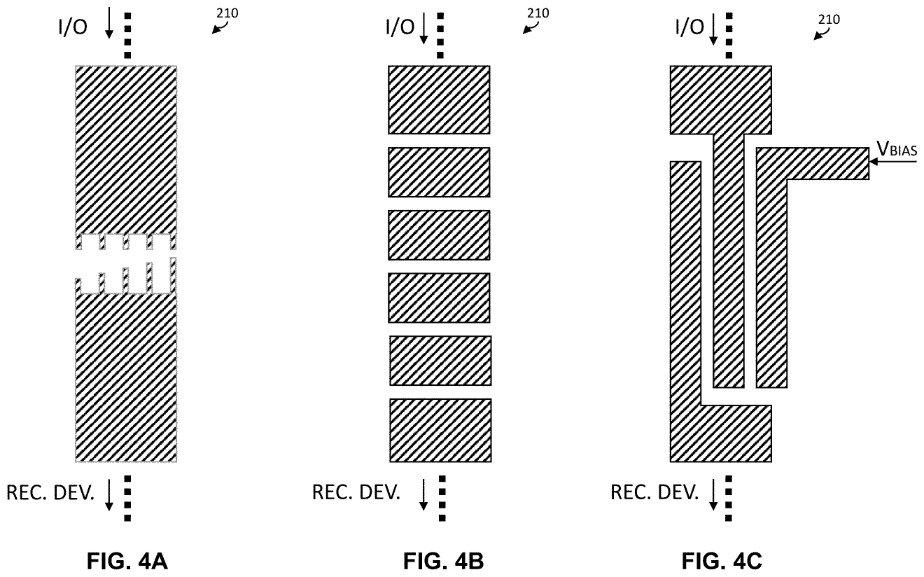

FIGS. 4A, 4B, and 4C are top views illustrating circuit traces for various implementations the spark-gap circuit of FIG. 2. FIG. 4A illustrates an example spark-gap circuit 210 having adjacent metal traces configured as parallel-connected spark gaps, each having a gap-width that is configured to conduct a signal above a different trigger voltage (i.e., conduct a signal of a particular amplifier). For example, a narrower gap-width may have a lower trigger voltage and therefore may conduct a signal of having an amplitude (e.g., voltage) lower than a wider gap-width. The particular amplitude of the conducted signal may correspond to the severity of the electrical event. Accordingly, a determination of which spark gap (or spark gaps) in the plurality conducted a signal may help determine a severity of the electrical event.

In another possible implementation the parallel-connected spark gaps each have the same gap-width. In other words, the spark-gap circuit may include a plurality of redundant spark gaps. One of the redundant spark gaps (i.e., a first spark gap) may be triggered during a first electrical event. Subsequently a second spark gap of may be triggered during a second electrical event. In this way multiple electrical events can be accommodated. Further, a visual examination of the redundant spark gaps for damage may reveal the number of electrical events experienced because each electrical event damages one of the redundant spark gaps.

FIG. 4B illustrates an example spark-gap circuit 210 having series-connected spark gaps. The spark gap circuit includes a metal trace on a substrate defining a plurality of series-connected spark gaps arranged sequentially along the metal trace. In the implication shown, the series-connected spark gaps have similar (e.g., the same) gap widths so that each of the spark gaps has is configured to conduct a signal above a trigger voltage. For a signal having an amplitude above the trigger voltage, each spark gap traversed reduces the amplitude of the signal. Accordingly, the number of spark gaps in the spark gap circuit 210 may correspond to an overall trigger voltage of the spark-gap circuit 210. For example, a plurality of series-connected spark gaps may correspond to a higher overall trigger voltage (i.e., threshold) than a single spark gap. Further, the number of series-connected spark gaps can be choses to provide a trigger voltage so that electrical events above a particular severity are conducted to the recording device.

FIG. 4C illustrates an example spark-gap circuit 210 that includes multiple metal traces on a substrate. The multiple metal traces are positioned in an interdigitated arrangement that defines spark gaps between pairs of the multiple metal traces in the interdigitated arrangement. The number of pairs and the spacing between pairs can (at least in part) determine an overall trigger voltage of the spark-gap circuit. Additionally, at least one of the metal traces is coupled to a bias circuit to be biased at a voltage (i.e., a bias voltage, V_{BIAS}) that is different from at least one of the other metal traces (e.g., different from all other traces). The spark-gap circuit 210 of FIG. 4C is configured to operate similar to a Marx ladder circuit in that the bias voltage can affect a trigger voltage (i.e., threshold) of the spark-gap circuit. Accordingly, the configuration of FIG. 4C may have advantageously have an adjustable trigger voltage based on the bias voltage. This can be contrasted with the configuration of FIG. 4B, which may have a trigger voltage that is fixed based on (at least) the number of spark gaps and the gap width of the spark gaps, or the configuration of FIG. 4A, which may have a set of trigger voltages based on (at least) the number of spark gaps and the gap width of the spark gaps.

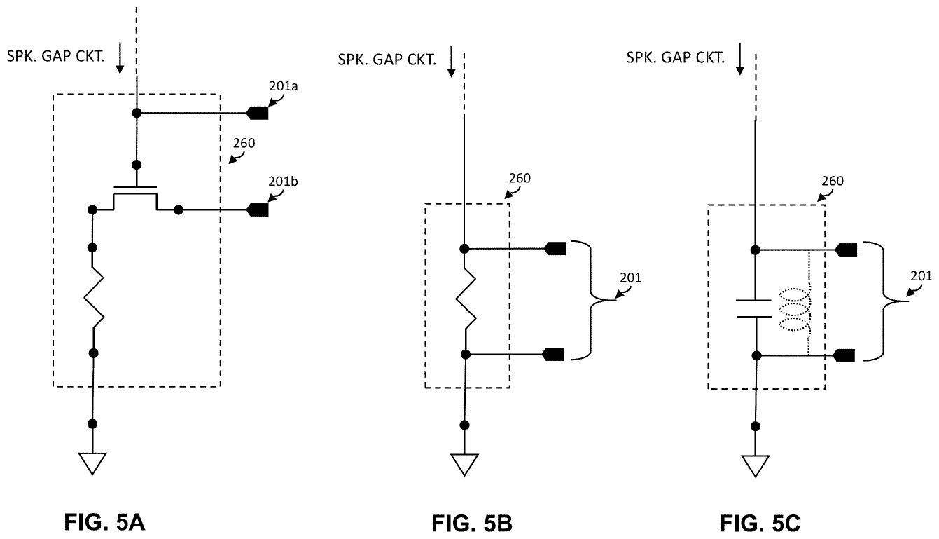

The recording device 260 of the event-recording circuit 200 may be implemented variously. FIGS. 5A, 5B, and 5C schematically illustrate possible implementations of a recording device. As shown in FIG. 5A, the recording device can include a transistor. The transistor is shown as a metal-oxide semiconductor field-effect transistor (MOSFET) but other implementations could use another technology (e.g., bipolar junction transistor, junction field-effect transistor, etc.). Further, the transistor is not limited to a particular type (e.g., N-type, P-type). For the implementation shown, a gate terminal of the transistor is coupled to the spark-gap circuit, while a source/drain terminal is coupled to a resistor. The resistor may be used to limit the current through the transistor when the transistor is turned ON (i.e., configured to conduct). The recording device 260 shown in FIG. 5A includes a diagnostic port. A first terminal 201a of the diagnostic port can be coupled to the gate of the transistor while a second terminal 201b can be coupled to a drain/source of the transistor.

When an electrical event occurs, the transistor may experience a voltage at the gate terminal that is large enough to affect (e.g., irreversibly affect) the operation of the transistor. In other words, a change (e.g., a non-transitory change, a permanent change, a non-volatile change, a long-term change, etc.) in the electrical property of the transistor can be caused (i.e., created, generated) by the signal conducted by the spark-gap circuit 210 during the electrical event. In a subsequent electrical test of the transistor, the test equipment can be coupled to the first terminal 201a and the second terminal 201b to measure the electrical property. For example, in one possible implementation a gate-oxide leakage current of the transistor may be measured. In another possible implementation, a threshold voltage of the transistor may be measured. The measured values may be compared to a baseline value (e.g., determined prior to use) to determine a change. The determined change can indicate that an electrical event has occurred and, in some cases, can correspond to the severity of an electrical event and/or a cumulative history of events.

As shown in FIG. 5B, the recording device 260 can be a resistive device, such as a poly-silicon resistor, phase change material (PCM), or a resistive random-access memory (i.e., ReRAM), in which the electrical property changed by the signal conducted by the spark-gap circuit is the resistance. For example, during an electrical event, the resistance may be reduced (e.g., permanently reduced, reduced for a period sufficient for a failure analysis) from a baseline resistance (i.e., a resistance before an electrical event). What is more, additional electrical events may further reduce the resistance of the recording device 260. In a subsequent, electrical test, test equipment (e.g., ohmmeter) may be coupled to the diagnostic port 201 of the recording device to measure the resistance. The resistance measured may be compared with a baseline value of resistance in order to determine a change in resistance. For implementations in which a control device 270 is included, the resistance of the recording device 260 may be compared to the resistance of the control device 270 to determine the change in resistance. The use of a control device 270 can eliminate the need to know a baseline resistance when determining the change in resistance.

Based on the change in resistance, it may be concluded that an electrical event (e.g., an EOS/ESD event) has occurred, which may be used for diagnosing damage to the internal circuit. Further, an amount of the change in resistance may correlate with a severity of an electrical event and/or a cumulative history of multiple electrical events.

As shown in FIG. 5C, the recording device 260 can be a field-effect device. In one possible implementation the field-effect device is a capacitor or MOS device. In this implementation, a leakage current of a capacitor or gate oxide leakage current of MOS device may be changed (e.g., increased) by a signal passed by the spark gap circuit during an electrical event. In another possible implementation, the field-effect device may be an inductor. The implementations illustrated in FIGS. 5A-5C are presented to help understanding, the present disclosure envisions that the recording device 260 can be implemented using multiple devices (e.g., resistor, capacitor, inductor, etc.) coupled in various topologies.

As mentioned previously, the spark gap may be fabricated as an encapsulated air-gap structure (i.e., air-gap). Encapsulating the air-gap using an inorganic dielectric, such as SiO₂, SiON, or SiN, can hermetically seal the air-gap from an outside environment (e.g., humidity, pressure, etc.). The inorganic dielectric encapsulation may have advantage over other encapsulation approaches (e.g., encapsulation using an organic material) because its ability to seal the air-gap from pressure or moisture changes, either of which can affect the trigger voltage for the air-gap. A trigger voltage for the air-gap that is stable in various environments can facilitate accurate measurements of electrical events.

The fabrication of the air-gap structure can use a semiconductor processes, including (but not limited to) deposition, photolithography, chemical etching, and the like. A variety of process flows may be used to form an encapsulated air-gap structure. It may be desirable to select a process flow for fabricating the encapsulating air-gap structure that matches the process flow used for fabricating the internal circuit 110 and/or event recording circuit 200 so that all these elements may be included in the same semiconductor device 100. In other words, forming a spark gap with no additional processing (other than already employed) or minimal additional processing may be desirable. In what follows, details regarding possible fabrication process flows for fabricating encapsulated air-gaps are presented. For the possible fabrication process flows presented, there may be a tradeoff between simplicity and size. For example, a process flow requiring fewer processing may require more area for the air-gap structure.

One possible process flow that can be used for fabricating an encapsulated air-gap structure includes forming metal traces (i.e., conductors, wires) in a dielectric, masking and etching the dielectric to form air-gaps and depositing a non-conformal dielectric over the air-gaps to encapsulate (i.e. seal, pinch-off) the air-gaps. For the non-conformal dielectric to seal the air-gap the gap width is be small (e.g., ≤0.2 microns). In some cases, after the air-gaps are etched and before the non-conformal dielectric is deposited, the surfaces of the structure are stripped and cleaned, and a conformal passivation layer is deposited on the surfaces. The dimensions of the air-gap may be controlled by the process. In some implementations, the air-gap has a lateral width that is smaller than the lateral width of the electrodes, while in other implementations the lateral width of the air-gap can be the same or larger than the lateral width of the electrodes.

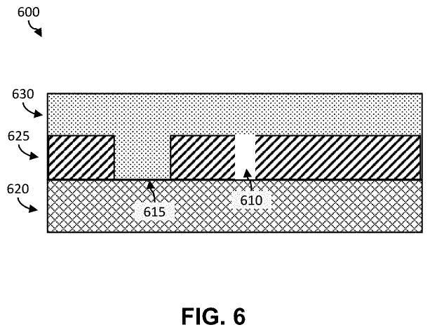

FIG. 6 is a cross-sectional side-view of an encapsulated-air-gap structure than can be implemented as a spark gap. The structure 600 includes a dielectric substrate 620 with a metal conductor 625 (e.g., Al) disposed on a top surface of the dielectric substrate 620. The metal may be patterned (e.g., via etching) to include a larger gap 615 and a smaller gap 610. The structure is covered by an inorganic dielectric (e.g., SiO₂) layer 630. The larger gap 615 and the smaller gap 610 are sized so that as a non-conformal inorganic dielectric layer is disposed on the structure, the larger gap is filled while the smaller gap is not filled (i.e., bridged, pinched off). The gap width of the smaller gap can be selected in range (e.g., ≤0.2 microns) so that the covering inorganic dielectric can pinch off the air-gap and so that a particular trigger voltage is provided.

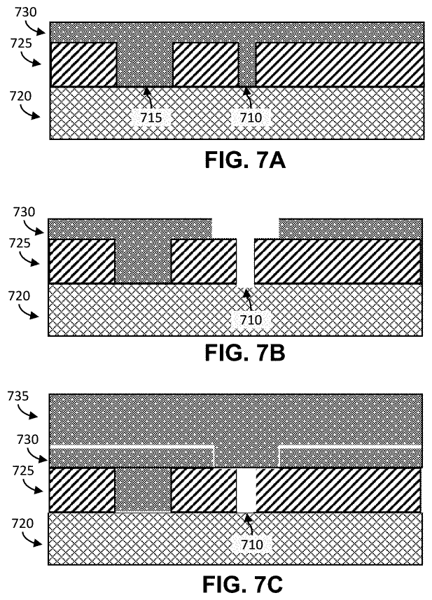

FIGS. 7A, 7B, and 7C are cross-sectional side-views of a possible encapsulated-air-gap structure at various stages of fabrication using semiconductor processing. As before, the structure includes a dielectric substrate 720 with a metal conductor 725 (e.g., Al) disposed on a top surface of the dielectric substrate 720. The metal conductor 725 may be patterned (e.g., via etching) to include a larger gap 715 and a smaller gap 710. The structure is covered by a first inorganic dielectric (e.g., SiO₂) layer 730. Unlike the previous implementation, in the implementation shown in FIG. 7A the inorganic dielectric fills the smaller gap 710 when it is deposited on a top surface of the structure.

As shown in FIG. 7B, the inorganic dielectric material in the smaller gap 710 may be removed using photolithographic and chemical processing. Finally, as shown in FIG. 7C, a second (non-conformal) dielectric layer 735 (e.g., a second SiO₂ layer) may be disposed on a top surface of the structure to cover the inorganic dielectric and the metal conductive layers while also encapsulating (i.e., sealing, pinching off) the smaller gap 710, which becomes the air-gap.

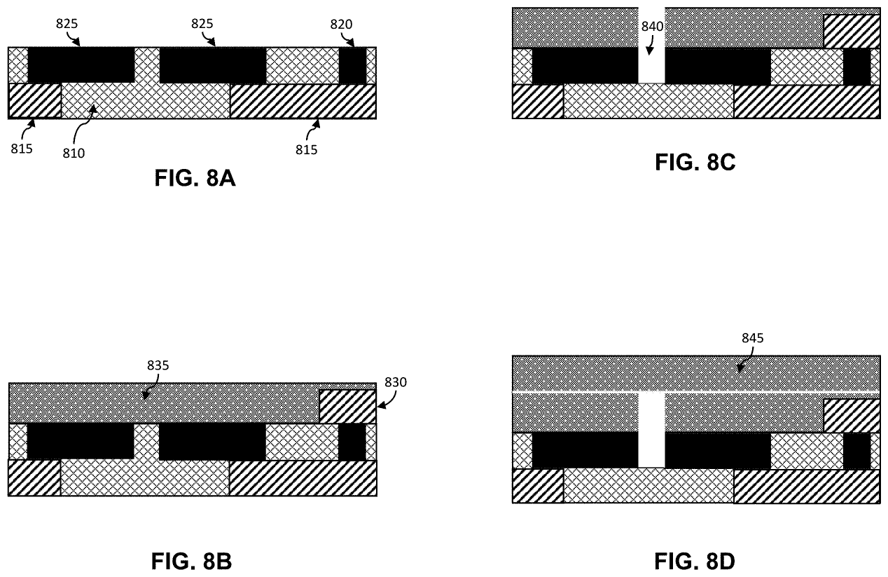

FIGS. 8A, 8B, 8C, and 8D are cross-sectional side-views of a possible encapsulated-air-gap structure at various stages of fabrication using semiconductor processing. Tungsten (i.e., W) may desirable for use in an air-gap structure (i.e., as a spark gap) because of its high melting temperature. Some semiconductor processes may be configured for fabricating circuit vias (i.e., vias) with tungsten. Accordingly, these semiconductor processes may be adapted to fabricate encapsulated air-gap structures using tungsten electrodes.

FIG. 8A is a side-view section of layers in an air-gap structure using tungsten electrodes. The structure includes a dielectric 810 that supports first metal layer. The first metal layer includes metal-3 aluminum traces 815 (i.e., M3 Al traces). The structure also includes a tungsten via 820. The conventional tungsten via is a post-like conductor for connecting different metal layers. The structure also includes via bars 825 configured as electrodes. Thus, a fabrication process configured to produce tungsten vias may be adapted to produce elongated tungsten vias 825 (i.e., via bars) that form the electrodes in a spark-gap. Next, as shown in FIG. 8B, a second metal layer that include metal-4 aluminum traces 830 (i.e., M4 Al) covered by a first inorganic dielectric layer 835 (e.g., a 1^{st} SiO₂ layer) is disposed on the structure of FIG. 8A. Next, as shown in FIG. 8C, an air-gap 840 is formed by masking and etching the air-gap 840 in the structure. Finally, as shown in FIG. 8D, the air-gap 840 is encapsulated (i.e., covered, sealed, pinched-off) by a second inorganic dielectric layer 845 (e.g., a 2^{nd} SiO₂ layer).

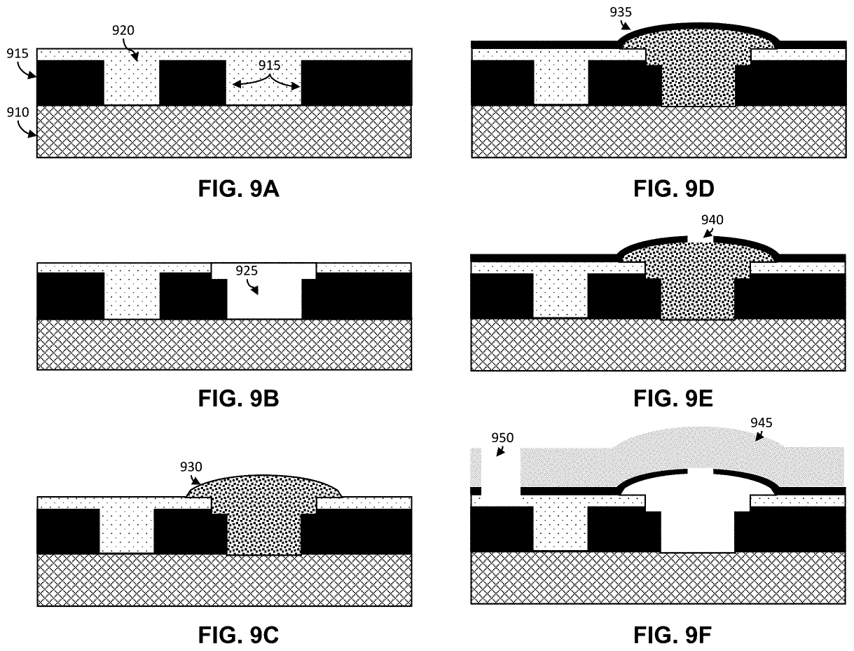

FIGS. 9A, 9B, 9C, 9D, 9E, and 9F are cross-sectional side-views of a possible encapsulated-air-gap structure at various stages of fabrication using semiconductor processing. So far, a gap-width (i.e., the spacing between electrodes) of an encapsulated air-gap structure has been based, at least, the non-conformal dielectric encapsulation. It may be desirable to use a process which reduces or eliminates constraints on a gap-width (e.g., that can produce a gap-width of any size). Some semiconductor processes have been adapted for micro mechanical electromagnetic structures (MEMS). These MEMS processes may be adapted to fabricate encapsulated air-gap structures with more control over the dimensions of the gap-width.

FIG. 9A is a side-view section of layers including a dielectric 910 having metal traces 915 covered by a first passivation layer 920. Next, as shown in FIG. 9B an air-gap 925 may be etched using masking (e.g., lithography) and etching (e.g., chemical etching). Next, as shown in FIG. 9C, the air-gap 925 can be filed using a sacrificial organic material 930 (e.g., a polymer). Next, as shown in FIG. 9D, a hard dielectric 935 (e.g., SiN) may be deposited on the structure, including the organic material 930. Next, as shown in FIG. 9E, a vent 940 is created in the hard dielectric 935. In other words, the organic material layer is vented. After venting, the organic material may be removed (e.g., using an oxygen plasma) to leave an air-gap structure between the metal traces 915. Finally, as shown in FIG. 9F, the hard dielectric 935 and the vent 940 can covered by an inorganic dielectric layer 945 that is deposited on the structure to encapsulate the air-gap 925. Additionally, at this step an opening to the metal traces (i.e., a pad 950) may be formed for access to the circuit.

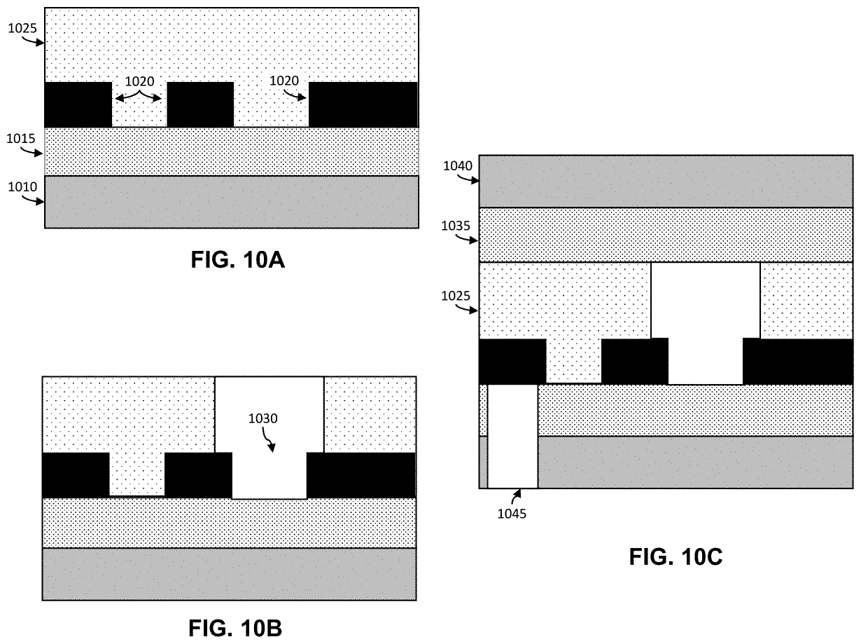

It may be desirable to use or adapt a wafer-bonding process to create an air-gap structure. For example, some applications, such as images sensors (e.g., a back-side illumination image sensor) may use this process. FIGS. 10A, 10B, and 10C are cross-sectional side-views of a possible encapsulated-air-gap structure at various stages of fabrication using a wafer-bonding process.

FIG. 10A is a side-view section of a structure including a first wafer 1010 (e.g., Si wafer), a dielectric 1015 (e.g., SiO₂) layer and metal traces 1020 (i.e., interconnects) covered by a planar passivation layer 1025. Next, as shown in FIG. 10B an air-gap 1030 is formed by masking and etching the planar passivation layer 1015. Finally, the air-gap 1030 is encapsulated by bonding an inorganic layer 1035 (e.g. SiO₂ layer) on a second wafer 1040 (i.e., handle wafer) to the etched planar passivation layer 1015. Additionally, a through-silicon via 1045 (i.e., TSV) may be formed to provide clearance for connection to a metal trace 1020 on the metal layer.

While various process flows have been presented variations may exist that do not depart from the scope of the disclosure, which presents spark gaps that can be fabricated with little or no additional processing in a process flow for a semiconductor device. For example, the novel approach of adapting tungsten vias (i.e., via bars) as spark gap electrodes can be used to create an air-gap structure that can be encapsulated with an organic material. For example, a mold compound (e.g., from the package housing) of a semiconductor device may be adapted to encapsulate the air-gap structure. The organic sealing material may be more permeable to an environment than the inorganic sealing materials described thus far but can be used in certain situations (e.g., for cost efficiency). In another example, the process flows may result in air-gaps having virtually any shape, including (but not limited to) rectangular, circular, triangular, and the like.

The disclosure provides an event-recording circuit that can monitor and record ESD/EOS events. The event-recording circuit can simplify and aid failure analysis (FA) of an internal circuit. For example, the FA of a customer return of the internal circuit can be simplified and FA information may be provided that helps determine if the internal circuit (i.e., the part) was operated outside of its specification limits. This determination may further help determine a business decision, such as whether to replace the part free of charge. The spark gap minimizes parasitic effects (e.g., current leakage, parasitic capacitance) on an I/O port because a recording device is not coupled to the circuit until an electrical event (e.g., ESD/EOS event) occurs. Further, the spark gap may not require any power consumption to perform this trigger voltage operation. The use of the spark gap provides versatility in the recording device design. For example, very simple recording device components and topologies may be used (e.g., see FIGS. 5A-5C), which can reduce size and cost. Alternatively, more complicated designs can be used. These more complicated designs may include additional complexity to expand capabilities in the monitoring, recording, or reporting (i.e., electrical interface) of the event-recording circuit. For example, the diagnostic port (and control-diagnostic port) may be coupled to pins of a device to eliminate any need for disassembly for a test associated with FA.

In the specification and/or figures, typical embodiments have been disclosed. The present disclosure is not limited to such exemplary embodiments. The use of the term “and/or” includes any and all combinations of one or more of the associated listed items. The figures are schematic representations and so are not necessarily drawn to scale. Unless otherwise noted, specific terms have been used in a generic and descriptive sense and not for purposes of limitation.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. A circuit for recording an electrical event, the circuit comprising:
a spark-gap circuit including at least one metal trace defining at least one spark gap, the at least one spark gap configured to conduct a signal during the electrical event;
a recording device coupled to the spark-gap circuit and configured to have an electrical property that is altered by the signal conducted during the electrical event; and
a diagnostic port configured to provide electrical access to the recording device for an electrical test of the electrical property that was altered by the signal conducted during the electrical event.

2. The circuit according to claim 1, wherein the circuit is directly coupled to an input/output port of an internal circuit to monitor the electrical event at the input/output port of the internal circuit.

3. The circuit according to claim 2, wherein the electrical event is an electrostatic discharge (ESD) at the input/output port of the internal circuit or an electrical over stress (EOS) on the internal circuit.

4. The circuit according to claim 1, wherein the at least one spark gap is at least one air-gap structure encapsulated by an inorganic dielectric.

5. The circuit according to claim 1, wherein the spark-gap circuit includes a plurality of metal traces arranged adjacent to one another on a substrate, the plurality of metal traces defining a plurality of parallel-connected spark gaps, each having a gap-width that is configured to conduct a signal of a particular amplitude, the particular amplitude corresponding to a severity of the electrical event.

6. The circuit according to claim 1, wherein the spark-gap circuit includes a metal trace on a substrate defining a plurality of series-connected spark gaps arranged sequentially along the metal trace on the substrate, each of the plurality of series-connected spark gaps having a gap width that is configured to conduct a signal of a particular amplitude, the particular amplitude corresponding to a severity of the electrical event.

7. The circuit according to claim 1, wherein the spark-gap circuit includes multiple metal traces on a substrate configured in an interdigitated arrangement, the multiple metal traces forming spark gaps between pairs of the multiple metal traces in the interdigitated arrangement on the substrate, wherein one of the multiple metal traces is coupled to a bias circuit so that it is at a voltage different from other traces in the multiple metal traces.

8. The circuit according to claim 1, wherein the recording device includes a transistor and the electrical property altered by the signal is a threshold voltage of the transistor.

9. The circuit according to claim 1, wherein the recording device is a field-effect device and the electrical property altered by the signal is a capacitance or an inductance of the field-effect device.

10. The circuit according to claim 1, further comprising:
a control device that is substantially equivalent to the recording device but that is not coupled to the spark-gap circuit; and
a control-diagnostic port configured to provide electrical access to the control device for an electrical test of an electrical property of the control device.

11. A method for diagnosing damage to an internal circuit, the method comprising:
receiving a signal at an input/output port of the internal circuit;
receiving the signal at a spark-gap circuit coupled to the input/output port, the spark-gap circuit including at least one metal trace defining at least one spark gap;
conducting the signal through the at least one spark gap during an electrical event;
receiving the signal conducted by the at least one spark gap at a recording device coupled to the spark-gap circuit, the recording device configured to have an electrical property altered by the conducted signal; and
coupling test equipment to a diagnostic port of the recording device;
performing an electrical test on the recording device to determine the electrical property altered by the conducted signal; and
diagnosing the damage to the internal circuit based on a result of the electrical test.

12. The method for diagnosing damage to an internal circuit according to claim 11, wherein the electrical event is an electrostatic discharge (ESD) or an electrical over stress (EOS) at the input/output port of the internal circuit.

13. The method for diagnosing damage to an internal circuit according to claim 11, wherein the at least one spark gap is a plurality of spark gaps, each configured to couple a signal of a different amplitude,

14. The method for diagnosing damage to an internal circuit according to claim 13, further comprising:
visually inspecting the plurality of spark gaps;
determining, based on the visual inspection, one or more spark gaps of the plurality of spark gaps as having coupled the signal during the electrical event;
correlating the one or more spark gaps determined to have coupled the signal during the electrical event to a signal amplitude; and
determining an amplitude of the signal during the electrical event based on the correlation.

15. The method for diagnosing damage to an internal circuit according to claim 11, wherein:
the recording device is a transistor;
the electrical property altered by the conducted signal is a threshold voltage of the transistor; and
the electrical test performed on the transistor is a measurement of the threshold voltage of the transistor.

16. The method for diagnosing damage to an internal circuit according to claim 11, wherein:
the recording device is a resistor;
the electrical property altered by the conducted signal is a resistance of the resistor; and
the electrical test performed on the resistor is a measurement of the resistance of the resistor.

17. The method for diagnosing damage to an internal circuit according to claim 11, wherein:
the recording device is a field-effect device; and
the electrical property altered by the conducted signal is a capacitance or an inductance of the field-effect device; and
the electrical test performed on the field-effect device is a measurement of the capacitance or the inductance of the field-effect device.

18. The method for diagnosing damage to an internal circuit according to claim 11, further comprising:
providing a control device that is substantially equivalent to the recording device but that receives no signal from the spark-gap circuit during the electrical event;
coupling test equipment to a control-diagnostic port of the control device;
performing an electrical test on the control device to determine an electrical property of the control device;
comparing the electrical property of the control device to the electrical property of the recording device altered by the conducted signal; and
diagnosing the damage to the internal circuit based on the comparison.

19. A semiconductor device comprising:
an internal circuit having an input/output port;
an event recording circuit configured to record an electrical event at the input/output port of the internal circuit to facilitate diagnosis of damage to the internal circuit, the event recording circuit including:
a spark-gap circuit including at least one metal trace defining at least one spark gap, the at least one spark gap configured to conduct a signal during the electrical event, the at least one spark gap is an air-gap structure that is encapsulated by an inorganic dielectric;
a recording device coupled to the at least one spark gap and is configured to have a property that is altered by the signal; and
a diagnostic port configured to provide access to the recording device for a test of the property altered by the signal.

20. The semiconductor device according to claim 19, further comprising:
a control device that is substantially equivalent to the recording device but that is not coupled to the spark-gap circuit; and
a control-diagnostic port configured to provide access to the control device for a test of a property of the control device.
